(19) United States
(12) Patent Application Publication
(10) Pub. No.: US 2026/0017434 A1
(43) Pub. Date: Jan. 15, 2026

(54) MUTUALLY GENERATIVE ARTIFICIAL INTELLIGENCE SYSTEM BASED ON MULTI-DIMENSIONAL SPATIOTEMPORAL INFORMATION VECTOR GRAPHICS

(71) Applicants: Beijing LongRuan Technologies Inc., Beijing (CN); PEKING UNIVERSITY, Beijing (CN)

(72) Inventors: Shanjun MAO, Beijing (CN); Pengpeng ZHANG, Beijing (CN); Ning CHEN, Beijing (CN); Haoyuan ZHANG, Beijing (CN)

(21) Appl. No.: 19/049,443

(22) Filed: Feb. 10, 2025

(30) Foreign Application Priority Data
Jul. 9, 2024 (CN) 202410915105.3

(51) Int. Cl. G06F 30/27; G06F 16/487

(52) U.S. Cl. CPC G06F 30/27; G06F 16/487

(57) ABSTRACT

Disclosed is a mutually generative artificial intelligence system based on multi-dimensional spatiotemporal information vector graphics, relating to the field of artificial intelligence and engineering applications. Based on a geographic information system (GIS) or a computer-aided design (CAD) platform and a data source, a multi-dimensional vector spatiotemporal large model terminal, a multi-dimensional spatiotemporal information processing agent terminal, and an intelligent information system application terminal are constructed. For multi-dimensional spatiotemporal data such as two-dimensional and three-dimensional vectors and temporal states, a multimodal spatiotemporal large model having an understanding capacity for an engineering professional knowledge system, a data processing flow, multi-dimensional vector graphics, and thematic graphics-text documents is pre-trained to achieve the mutual expression and generation of engineering multi-dimensional vector graphics and thematic graphics-text documents and to form an intelligent engineering graphic data processing application.

### TECHNICAL FIELD

The present disclosure relates to the field of artificial intelligence technology and engineering applications and more particularly, to a mutually generative artificial intelligence system based on multi-dimensional spatiotemporal information vector graphics.

### BACKGROUND

In recent years, an artificial intelligence technology represented by a large model has developed rapidly. A large model technology is based on huge data set training, showing strong semantic understanding and reasoning capacities, and showing an application potential for solving complex problems in the fields of speech, translation, medicine, education, finance, art, and the like. A multimodal large model combines capacities of the large model in natural language processing with capacities for understanding and generating other modal data (such as vision and audio). By integrating multiple types of input and output such as text, images, and sound, the characteristics of multimodal information processing in a human cognitive process are imitated, and a richer and more natural interactive experience is provided. However, at present, the artificial intelligence technology, including the multimodal large model, still processes types of data such as text, speech, images, and videos, which are essentially in textual and raster formats. The artificial intelligence technology mainly serves fields such as literary and artistic creation, question answering system, speech translation, and data summarization and analysis, and has not yet involved the human engineering application field characterized by vector format data. Since birth, human beings are faced with rich multimedia spatiotemporal data in the real world, involving various types such as text, audio, video, graphics, and images, as well as complex features such as numbers, text, attributes, metadata, interactive flows, and spatiotemporal relationships. Therefore, the human beings have intelligence and even wisdom. Language is only an organic component of the multimedia spatiotemporal data, and the human beings mainly represent and interpret data in text, as well as vector and raster graphic image formats. Artificial intelligence is not only the current text or statistical intelligence or spatial intelligence based on machine vision, but also spatiotemporal AI (STAI). The large model will evolve into a spatiotemporal large model (STLM) in the future. A large language model (LLM) is just a subset of STLM. In a spatiotemporal intelligent processing system, a vector model occupies an important position and is widely used.

A geographic information system (GIS) is a computer system with a task of collecting, storing, managing, calculating, analyzing, displaying, and describing the location distribution of geospatial objects and solving problems of users. Computer-aided design (CAD) is a computer system that provides engineering designers with geometric modeling, feature computing, computer drawing, and other functions using a computer and graphic equipment thereof. At present, the GIS and the CAD have been widely used in the fields of spatial data management, engineering design and drawing, and have accumulated massive graphics-related data, including electronic maps, engineering design drawings, production and construction drawings, and the like, which all are of data types dominated by vector spatial data. Vector data is essentially an abstract data format, which is an abstract expression of spatial objects and engineering processes by the human beings. Either the GIS or the CAD completes vector graphics drawing through manual interaction, followed by the manual writing of thematic graphics-text documents based on a human knowledge system and actual engineering requirements. Since the GIS has a topological spatial relationship, the GIS can achieve partial automatic processing, while the CAD is unlikely to achieve intelligent processing due to lack of the description of spatiotemporal relationships and the complete expression of attributes. In general, at present, the drawing of vector graphics and the processing of thematic graphics-text engineering documents related to the GIS and the CAD are one-way, not two-way intelligent mutual generation, making it impossible to achieve intelligent automatic processing.

The large model technology provides the possibility for the mutual generation of the vector graphics and the graphics-text documents, but at present, the research or application of the large model still focuses on the text or raster type data, involving applications such as text-to-raster video, and rarely involving the modeling of vector data such as points, lines, polygons, solids, and networks. Therefore, it is urgent to provide a system for understanding, analyzing, and processing multi-dimensional spatiotemporal information vector graphics and mutually generating the thematic graphics-text documents to meet requirements for processing a large number of multi-dimensional vector graphics and thematic graphics-text documents in human engineering application fields.

### SUMMARY

In view of the aforementioned problems, the present disclosure provides a mutually generative artificial intelligence system based on multi-dimensional spatiotemporal information vector graphics.

Embodiments of the present disclosure provide a mutually generative artificial intelligence system based on multi-dimensional spatiotemporal information vector graphics. The mutually generative artificial intelligence system includes: a multi-dimensional vector spatiotemporal large model terminal, a multi-dimensional spatiotemporal information processing agent terminal, and an intelligent information system application terminal.

The multi-dimensional vector spatiotemporal large model terminal is configured for uniformly modelling and expressing multiple types of spatiotemporal data, and constructing a multimodal vector spatiotemporal large model. The vector spatiotemporal large model is used for mutual expression, understanding, and analysis of multi-dimensional vector spatiotemporal data and a natural language description including speech and text, so as to achieve enhanced learning of vertical field knowledge of an engineering professional knowledge system, and further strengthen a processing capacity for engineering field knowledge and a data processing flow. The multiple types of spatiotemporal data include: text, speech, images, videos, and multi-dimensional vector graphics.

The multi-dimensional spatiotemporal information processing agent terminal is configured for learning and referring to a task execution process of a typical service flow based on learning and reasoning capacities of the vector spatiotemporal large model in combination with processing and analysis capacities of a geographic information system (GIS) or a computer-aided design (CAD) platform, automatically analyzing a service flow task for processing interaction of various types of multi-dimensional spatiotemporal data, decomposing the service flow task into simple sub-tasks, and autonomously executing, transmitting, and solving the sub-tasks.

The intelligent information system application terminal is configured for converting various types of multi-dimensional spatiotemporal data into corresponding natural language descriptions based on reasoning and understanding capacities of the vector spatiotemporal large model to achieve artificial intelligence understanding of the multi-dimensional vector graphics and various types of multi-dimensional spatiotemporal data, completing agent-driven interaction, analysis, and mutual generation of the multi-dimensional vector graphics and thematic graphics-text documents in an engineering field via a simple input mode including the speech and the text, accurately acquiring parameters in the multi-dimensional spatiotemporal data via a reasoning capacity of the vector spatiotemporal large model and a processing capacity of the agent, automatically updating related multi-dimensional spatiotemporal data, and further achieving automatic generation and updating of the multi-dimensional vector graphics or the thematic graphics-text documents.

Optionally, the multi-dimensional vector spatiotemporal large model terminal is embedded with field knowledge of the engineering professional knowledge system to achieve enhanced learning of vertical field knowledge of the engineering professional knowledge system and to strengthen the understanding and execution capacities of the engineering field knowledge and the data processing flow.

The process of constructing the vector spatiotemporal large model by the multi-dimensional vector spatiotemporal large model terminal includes: the natural language description of the multi-dimensional vector spatiotemporal data, pre-training and fine-tuning of the vector spatiotemporal large model, and understanding and analysis of the multi-dimensional vector spatiotemporal data.

Embedding the multi-dimensional vector spatiotemporal large model terminal with the field knowledge of the engineering professional knowledge system to achieve enhanced learning of vertical field knowledge of the engineering professional knowledge system includes: fine-tuning a general large model using engineering field data as a pre-training data set, and using the pre-training data set to pre-train the general large model by expanding an engineering vertical field vocabulary to achieve knowledge embedding of the field knowledge of the engineering professional knowledge system into the general large model.

Embedding the multi-dimensional vector spatiotemporal large model terminal with field knowledge of the engineering graphics-text data processing flow to strengthen the understanding and execution capacities of the engineering field knowledge and the data processing flow specifically includes: describing a processing flow of data with clear engineering characteristics, defining a language of the processing flow of the engineering field data, training the general large model using the uniformly expressed processing flow of the engineering field data as a fine-tuning data set to achieve knowledge embedding of the data processing flow, and strengthening understanding and execution capacities of the general large model for the processing flow of the engineering field data.

The natural language description of the multi-dimensional vector spatiotemporal data includes, but is not limited to, description conversion of various types of vector spatiotemporal data of points, lines, polygons, and solids having continuous spatial temporal (x, y, z, t) information and attribute information in various fields including the GIS and the CAD in a natural language mode according to requirements for training, understanding, and processing the vector spatiotemporal large model. The converted natural language description has all information of original vector spatiotemporal data, including but not limited to geometric types, geometric features, display styles, reference point coordinates, relative geometric data based on reference points, temporal information, and attribute information of vector objects.

The pre-training and fine-tuning of the vector spatiotemporal large model includes: establishing a data set including the natural language description of the multi-dimensional vector spatiotemporal data and vector object features, and continuously pre-training and fine-tuning the general large model based on the pre-training data set and the fine-tuning data set to form the vector spatiotemporal large model having an understanding capacity for vector spatiotemporal data.

The understanding and analysis of the multi-dimensional vector spatiotemporal data includes: inputting vector spatiotemporal data of the natural language description to the vector spatiotemporal large model, outputting understood vector object features by the vector spatiotemporal large model, inputting partial vector object features to the vector spatiotemporal large model, outputting understood or analyzed complete vector spatiotemporal data by the vector spatiotemporal large model, and based on output vector object spatiotemporal features or data, further completing understanding and processing of the geometric features, understanding and processing of attribute features, determination and processing of spatial relationships, and determination and processing of spatiotemporal relationships of the vector spatiotemporal data via an analysis capacity of the vector spatiotemporal large model.

The understanding and processing of the geometric features of the vector spatiotemporal data includes: processing geometric coordinates of the vector objects themselves, including but not limited to modification and editing of shape, size, and position.

The understanding and processing of the attribute features of the vector spatiotemporal data includes: processing attribute information of the vector objects themselves, including but not limited to modification, query, analysis, and statistics.

The determination and processing of the spatial relationships of the vector spatiotemporal data includes: determining and processing a topological spatial relationship, a sequential spatial relationship, and a metric spatial relationship between the vector objects. The topological spatial relationship refers to association, adjacency, inclusion, intersection, overlap, and separation relationships between spatial objects. The sequential spatial relationship refers to a spatial arrangement sequence of the spatial objects or events, including positional relationships such as front-back, left-right, up-down, and east-west-north-south. The metric spatial relationship refers to a distance or proximity relationship between the spatial objects.

Optionally, the multi-dimensional spatiotemporal information processing agent terminal includes: a task planning module, a task memory module, and a task action module. The task planning module, the task memory module, and the task action module respectively represent a corresponding processor.

The task planning module is configured for decomposing and planning sub-tasks of a vector graphics processing interactive service flow included in various types of multi-dimensional spatiotemporal data processing based on field knowledge, service flows, data understanding, and text generation capacities of the vector spatiotemporal large model. The sub-tasks are independently executed general logic processing or geographic information spatial analysis operation, have clear input and output, and are executed in conjunction to complete complex service flow processing.

The task memory module is configured for sensing, by the tasks, information from the environment or acquire information from storage, providing required data for the tasks, and storing process data in execution. Through the task memory module, the multi-dimensional spatiotemporal information vector processing agent accumulates data and experience, and gradually completes self-evolution to provide an iterative capacity support for the vector spatiotemporal large model.

The task action module is configured for executing the sub-tasks planned by the vector spatiotemporal large model as a specific result. The task execution process depends on, but is not limited to, the reasoning capacity of the vector spatiotemporal large model, the spatial analysis and processing capacities of the geographic information system, and the processing capacity of the computer-aided design system. Interactive objects in the execution process include, but are not limited to, sensors, model libraries, controllers, and databases.

Optionally, the step of achieving artificial intelligence understanding of the multi-dimensional vector graphics and various types of multi-dimensional spatiotemporal data, and interaction, analysis, and mutual generation of the multi-dimensional vector graphics and the thematic graphics-text documents by the intelligent information system application terminal includes: processing and understanding the multi-dimensional spatiotemporal data, generating the multi-dimensional spatiotemporal data processing agent, and mutually generating the multi-dimensional vector graphics and the thematic graphics-text documents, and specifically includes the following steps:
step S1: inputting the multi-dimensional spatiotemporal data into the intelligent information system application terminal, converting the multi-dimensional spatiotemporal data into a natural language description processable for the vector spatiotemporal large model, and based on the reasoning and understanding capacities of the vector spatiotemporal large model, performing artificial intelligence analysis and understanding of multi-dimensional spatiotemporal information vector data and temporal data in the multi-dimensional spatiotemporal data;
step S2: inputting user instructions in an interactive mode including speech input and text input, based on the understanding, analysis, and processing capacities of the vector spatiotemporal large model, and converting the user instruction input of the natural language description into formatted information system data edition, query, analysis, and output instructions to achieve generation of the multi-dimensional spatiotemporal data processing agent, wherein the speech input is converted into text via speech recognition; and
step S3: based on the multi-dimensional spatiotemporal information processing agent, performing fusion call and multi-round execution using the multi-dimensional spatiotemporal information processing agent to achieve automatic, intelligent automatic generation of the multi-dimensional vector graphics and the thematic graphics-text documents and bidirectional update of mutually generative artificial intelligence applications, and to achieve mutual generation of the multi-dimensional vector graphics and various types of multi-dimensional spatiotemporal data.

Optionally, establishing the data set including the natural language description of the multi-dimensional vector spatiotemporal data and the vector object features, and continuously pre-training and fine-tuning the general large model based on the pre-training data set and the fine-tuning data set specifically includes the following steps:
step T1: collecting massive vector spatiotemporal data, text natural language descriptions corresponding to the vector spatiotemporal data, and feature descriptions of the vector objects to form a vector spatiotemporal training data set, wherein the vector spatiotemporal data includes predefined geometric structure information of points, lines, polygons, and solids, and attribute text information corresponding to geometry;
step T2: performing pre-training on the general large model as a base using the vector spatiotemporal training data set, performing vector text sampling as a training sample by random walking, and inputting the training sample to the general large model in a GPT generation mode for model fine-tuning to achieve effective injection of vector information knowledge; and
step T3: collecting a plurality of question answering pattern data including vector data-topological relationship, vector data-attribute information, and attribute description-vector data, forming a vector spatiotemporal model fine-tuning data set, and fine-tuning the general large model pre-trained in step T2 to achieve effective alignment between natural languages and vector data.

Optionally, the task planning module retrieves similar tasks in an engineering flow library according to a task description. A task planning mode includes no-feedback planning and feedback planning. An execution result from an environment, a user, or the vector spatiotemporal large model is fed back, a service flow is decomposed into a plurality of sub-tasks for execution, the plurality of sub-tasks are connected together in a cascade or tree-like mode, and after each sub-task is completed, a subsequent sub-task is determined according to a task execution result.

Optionally, the task memory module stores information sensed from the environment, a task execution record, and a task execution result, and facilitates future actions using recorded memories. The task memory module includes memorized data and operations.

The memorized data includes a short-term memory of input information within a context window and a long-term memory of external vector storage retrieved by quick query.

Optionally, the task action module executes and completes various tasks using a tool. The tool specifically includes the vector spatiotemporal large model itself and external tools, including algorithm models, program compilation, databases, and application programming interfaces (APIs). The task action module further performs partial spatial analysis using a spatial database, completes specific tasks using models in a model library, and acquires real-time or historical data using an API. The specific tasks refer to tasks corresponding to the models in the model library.

Optionally, achieving the automatic generation of the multi-dimensional vector graphics or the thematic graphics-text documents includes:
according to content requirements for the multi-dimensional vector graphics and the thematic graphics-text documents, artificially formulating a multi-dimensional vector graphics or thematic graphics-text document template, or automatically generating a thematic graphics-text document template by the vector spatiotemporal large model according to the content requirements, wherein graphics in the thematic graphics-text documents are in a multi-dimensional vector graphics format or a raster format converted from the multi-dimensional vector graphics; and
through the query and analysis of an information system or the understanding and reasoning of the vector spatiotemporal large model, extracting and generating various types of parameters in the multi-dimensional vector graphics or thematic graphics-text document template, accurately acquiring parameters in the multi-dimensional vector spatiotemporal data, and fusing the parameters with the template to generate the multi-dimensional vector graphics or the thematic graphics-text documents.

Optionally, the multi-dimensional vector graphics and the thematic graphics-text documents are mutually generative based on the understanding and analysis capacities of the vector spatiotemporal large model, after related spatiotemporal information changes caused by entering the engineering field data or the thematic graphics-text documents, updated parameters, descriptions, or agents of the multi-dimensional vector graphics are generated by the vector spatiotemporal large model, and data of the multi-dimensional vector graphics is automatically updated.

After the multi-dimensional vector graphics change caused by drawing or modifying the multi-dimensional vector graphics, the changed multi-dimensional vector graphics are acquired by the vector spatiotemporal large model, corresponding engineering parameters or document descriptions are updated, and related contents of the thematic graphics-text documents are further updated to achieve the mutual generation of the multi-dimensional vector graphics and the thematic graphics-text documents.

In the present disclosure, based on a GIS or a CAD platform and a data source, a multi-dimensional vector spatiotemporal large model terminal, a multi-dimensional spatiotemporal information processing agent terminal, and an intelligent information system application terminal are constructed. For multi-dimensional spatiotemporal data such as two-dimensional and three-dimensional vectors and temporal states, a large model having an understanding capacity for an engineering professional knowledge system, a data processing flow, multi-dimensional vector graphics, and thematic document structures is pre-trained to achieve the mutual expression and generation of the multi-dimensional vector graphics, thematic spatiotemporal information, and professional document descriptions and to form an intelligent engineering field data processing system application. By establishing an artificial intelligence system in a human society engineering field, engineering technicians will be completely liberated, and an intelligent system support will be provided for automatic and rapid mutual processing of speech, text, the multi-dimensional vector graphics, and the thematic graphics-text documents in the related field. The present disclosure has higher practicability.

### BRIEF DESCRIPTION OF THE DRAWINGS

Various other advantages and benefits will become apparent to a person of ordinary skill in the art upon reading the following detailed description of preferred implementations. The drawings are only for purposes of illustrating the preferred implementations and are not to be construed as limiting the present disclosure. Also, throughout the drawings, the same reference numerals represent the same components. In the drawings:

FIG. 1 is a structural block diagram of a mutually generative artificial intelligence system based on multi-dimensional spatiotemporal information vector graphics provided by an embodiment of the present disclosure;

FIG. 2 is a flow chart of an application of an intelligent information system application terminal based on a vector spatiotemporal large model according to an embodiment of the present disclosure;

FIG. 3 is a flow chart of achieving interaction, analysis, and mutual generation of vector graphics and graphics-text documents based on a vector spatiotemporal large model according to an embodiment of the present disclosure; and

FIG. 4 is a schematic diagram of another embodiment of a mutually generative artificial intelligence system based on multi-dimensional spatiotemporal information vector graphics provided by an embodiment of the present disclosure.

### DETAILED DESCRIPTION

In order to make the aforementioned objects, features, and advantages of the present disclosure more apparent, the present disclosure will be described in further detail below with reference to the accompanying drawings and detailed description. It should be understood that specific embodiments described herein are merely for illustration of the present disclosure, are only some embodiments of the present disclosure, but not all embodiments, and are not intended to limit the present disclosure.

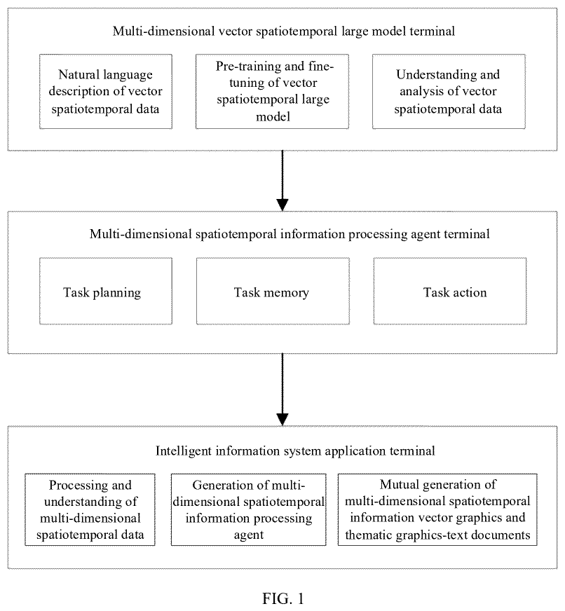

Referring to FIG. 1, a structural block diagram of a mutually generative artificial intelligence system based on multi-dimensional spatiotemporal information vector graphics according to this embodiment is shown. The mutually generative artificial intelligence system specifically includes: a multi-dimensional vector spatiotemporal large model terminal, a multi-dimensional spatiotemporal information processing agent terminal, and an intelligent information system application terminal. Among them, an agent refers to an independent small module or application that can complete a single task, and an information processing agent refers to a small module of information processing.

The multi-dimensional vector spatiotemporal large model terminal is configured to uniformly model and express multiple types of spatiotemporal data. In other words, the terminal uniformly models and expresses various types of spatiotemporal data. The types of the spatiotemporal data include: text, speech, images, video, multi-dimensional vector graphics, and the like.

The multi-dimensional vector spatiotemporal large model terminal is further configured to construct a multimodal vector spatiotemporal large model. The multimodal vector spatiotemporal large model is used for mutual expression, understanding, and analysis of multi-dimensional vector spatiotemporal data and a natural language description including speech and text, so as to achieve enhanced learning of vertical field knowledge of an engineering professional knowledge system, and further strengthen a processing capacity for engineering field knowledge and a data processing flow.

Preferably, the multi-dimensional vector spatiotemporal large model terminal is embedded with field knowledge of the engineering professional knowledge system to achieve enhanced learning of the vertical field knowledge of the engineering professional knowledge system and to strengthen the understanding and execution capacities of the engineering field knowledge and the data processing flow.

The process of constructing the vector spatiotemporal large model by the multi-dimensional vector spatiotemporal large model terminal includes: natural language description of the multi-dimensional vector spatiotemporal data, pre-training and fine-tuning of the vector spatiotemporal large model, and understanding and analysis of the multi-dimensional vector spatiotemporal data. In order to better express a structure of the mutually generative artificial intelligence system in FIG. 1, elements of constructing the vector spatiotemporal large model by the multi-dimensional vector spatiotemporal large model terminal are illustratively shown, which does not mean that the multi-dimensional vector spatiotemporal large model terminal is only configured to construct the vector spatiotemporal large model. The elements of constructing the vector spatiotemporal large model by the multi-dimensional vector spatiotemporal large model terminal include: natural language description of the vector spatiotemporal data (i.e., the natural language description of the multi-dimensional vector spatiotemporal data), pre-training and fine-tuning of the vector spatiotemporal large model (i.e., the pre-training and the fine-tuning of the vector spatiotemporal large model), and understanding and analysis of the vector spatiotemporal data (i.e., understanding and analysis of the multi-dimensional vector spatiotemporal data).

Embedding the multi-dimensional vector spatiotemporal large model terminal with the field knowledge of the engineering professional knowledge system to achieve enhanced learning of the vertical field knowledge of the engineering professional knowledge system specifically includes: fine-tuning a general large model using engineering field data as a pre-training data set, and using the pre-training data set to pre-train the general large model by expanding an engineering vertical field vocabulary to achieve knowledge embedding of the field knowledge of the engineering professional knowledge system into the general large model. Among them, the general large model, also known as the “base large model”, refers to a large language model that can cross fields and tasks. It is generally trained by large institutions and focuses more on the generality and generalization ability of the model. Correspondingly, the spatiotemporal large model in this specification is a field vertical large model, which enhances the ability in specific directions on the basis of the general large model.

Embedding the multi-dimensional vector spatiotemporal large model terminal with field knowledge of the engineering field data processing flow to strengthen the understanding and execution capacities of the engineering field knowledge and the data processing flow specifically includes: describing a processing flow of data with clear engineering characteristics, defining a language of the processing flow of the engineering field data, training the general large model using the uniformly expressed processing flow of the engineering field data as a fine-tuning data set to achieve knowledge embedding of the data processing flow, and strengthening understanding and execution capacities of the general large model for the processing flow of the engineering field data.

The natural language description of the multi-dimensional vector spatiotemporal data includes, but is not limited to, description conversion of various types of vector spatiotemporal data of points, lines, polygons, and solids having continuous spatial temporal (x, y, z, t) information and attribute information in various fields including a geographic information system (GIS) and computer-aided design (CAD) in a natural language mode according to requirements for training, understanding, and processing the vector spatiotemporal large model. The converted natural language description has all information of original vector spatiotemporal data, including but not limited to geometric types, geometric features, display styles, reference point coordinates, relative geometric data based on reference points, temporal information, and attribute information of the vector objects.

The pre-training and fine-tuning of the vector spatiotemporal large model specifically includes: establishing a data set including the natural language description of the multi-dimensional vector spatiotemporal data and vector object features, and continuously pre-training and fine-tuning the general large model based on the pre-training data set and the fine-tuning data set to form a vector spatiotemporal large model having an understanding capacity for vector spatiotemporal data.

Preferably, the method of establishing the data set including the natural language description of the multi-dimensional vector spatiotemporal data and the vector object features and continuously pre-training and fine-tuning the general large model based on the pre-training data set and the fine-tuning data set specifically includes the following steps:
Step T1: collecting massive vector spatiotemporal data, text natural language descriptions corresponding to the vector spatiotemporal data, and feature descriptions of the vector objects to form a vector spatiotemporal training data set, wherein the vector spatiotemporal data includes predefined geometric structure information of points, lines, polygons, and solids, and attribute text information corresponding to geometry.
Step T2: performing pre-training on the general large model as a base using the vector spatiotemporal training data set, performing vector text sampling as a training sample by random walking, and inputting the training sample to the general large model in a GPT generation mode for model fine-tuning to achieve effective injection of vector information knowledge.
Step T3: collecting a plurality of question answering pattern data including vector data-topological relationship, vector data-attribute information, and attribute description-vector data, forming a vector spatiotemporal model fine-tuning data set, and fine-tuning the general large model pre-trained in step T2 to achieve effective alignment between natural languages and vector data.

Through the method including the aforementioned three steps, the vector spatiotemporal large model is constructed by the multi-dimensional vector spatiotemporal large model terminal.

The understanding and analysis of the multi-dimensional vector spatiotemporal data includes: inputting vector spatiotemporal data of the natural language description to the vector spatiotemporal large model, outputting understood vector object features by the vector spatiotemporal large model, inputting partial vector object features to the vector spatiotemporal large model, outputting understood or analyzed complete vector spatiotemporal data by the vector spatiotemporal large model, and based on output vector object spatiotemporal features or data, further completing understanding and processing of geometric features, understanding and processing of attribute features, determination and processing of spatial relationships, and determination and processing of spatiotemporal relationships of vector spatiotemporal data via an analysis capacity of the vector spatiotemporal large model.

The understanding and processing of geometric features of vector spatiotemporal data includes: processing the geometric coordinates of the vector objects themselves, including but not limited to modification and editing of shape, size, and position. The understanding and processing of attribute features of vector spatiotemporal data includes: processing the attribute information of the vector objects themselves, including but not limited to modification, query, analysis, and statistics. The determination and processing of spatial relationships of vector spatiotemporal data includes: determining and processing a topological spatial relationship, a sequential spatial relationship, and a metric spatial relationship between the vector objects. The topological spatial relationship refers to association, adjacency, inclusion, intersection, overlap, and separation relationships between spatial objects. The sequential spatial relationship refers to a spatial arrangement sequence of the spatial objects or events, including positional relationships such as front-back, left-right, up-down, and east-west-north-south. The metric spatial relationship refers to a distance or proximity relationship between the spatial objects.

The multi-dimensional spatiotemporal information processing agent terminal is configured to learn and refer to a task execution process of a typical service flow based on learning and reasoning capacities of the vector spatiotemporal large model in combination with processing and analysis capacities of a GIS or a CAD platform, automatically analyze a service flow task for processing interaction of various types of multi-dimensional spatiotemporal data, decompose the service flow task into simple sub-tasks, and autonomously execute, transmit, and solve the sub-tasks. Among them, the typical service flow refers to the flow and steps of processing the spatiotemporal information data mentioned in this specification. Here, it refers to the methods of related data processing in the GIS and the CAD, such as graphic drawing, editing, adding attributes, spatial analysis processing, etc.

Preferably, the multi-dimensional spatiotemporal information processing agent terminal includes: a task planning module, a task memory module, and a task action module.

The task planning module is configured to decompose and plan sub-tasks of a vector graphics processing interactive service flow included in various types of multi-dimensional spatiotemporal data processing based on field knowledge, service flows, data understanding, and text generation capacities of the vector spatiotemporal large model. The sub-tasks are independently executed general logic processing or geographic information spatial analysis operation, have clear input and output, and are executed in conjunction to complete complex service flow processing. Specifically, the task planning module may firstly retrieve similar tasks in an engineering flow library according to a task description. A task planning mode includes no-feedback planning and feedback planning. An execution result from an environment, a user, or the vector spatiotemporal large model may be fed back, a service flow is decomposed into a plurality of sub-tasks for execution, the plurality of sub-tasks are connected together in a cascade or tree-like mode, and after each sub-task is completed, a subsequent sub-task is determined according to a task execution result.

The task memory module is configured to sense, by the tasks, information from the environment or acquire information from storage, provide required data for the tasks, and store process data in execution. Through the task memory module, the multi-dimensional spatiotemporal information vector processing agent may accumulate data and experience and gradually complete self-evolution to provide an iterative capacity support for the vector spatiotemporal large model. Specifically, the task memory module may store information sensed from the environment, a task execution record, and the task execution result, and facilitates future actions using recorded memories. The task memory module includes memorized data and operations. The memorized data includes a short-term memory of input information within a context window and a long-term memory of external vector storage retrieved by quick query.

The task action module is configured to execute the sub-tasks planned by the vector spatiotemporal large model as a specific result. The task execution process depends on, but is not limited to, the reasoning capacity of the vector spatiotemporal large model, the spatial analysis and processing capacities of the geographic information system, and the processing capacity of the computer-aided design system. Interactive objects in the execution process include, but are not limited to, sensors, model libraries, controllers, and databases. Specifically, the task action module can execute and complete various tasks using a tool. The tool specifically includes the vector spatiotemporal large model itself and external tools, including algorithm models, program compilation, databases, application programming interfaces (APIs), and the like. The task action module may further perform partial spatial analysis using a spatial database, complete specific tasks using models in a model library, and acquire real-time or historical data using an API. The so-called specific tasks refer to tasks corresponding to the models in the model library.

In order to better express the structure of the mutually generative artificial intelligence system in FIG. 1, the three modules of the multi-dimensional spatiotemporal information processing agent terminal are illustratively shown, which does not mean that the multi-dimensional spatiotemporal information processing agent terminal includes only three modules. The multi-dimensional spatiotemporal information processing agent terminal includes three modules: task planning (i.e., task planning module), task memory (i.e., task memory module), and task action (i.e., task action module).

The intelligent information system application terminal is configured to convert various types of multi-dimensional spatiotemporal data into corresponding natural language descriptions based on reasoning and understanding capacities of the vector spatiotemporal large model to achieve artificial intelligence understanding of the multi-dimensional vector graphics and various types of multi-dimensional spatiotemporal data, complete agent-driven interaction, analysis, and mutual generation of the multi-dimensional vector graphics and thematic graphics-text documents in an engineering field via a simple input mode including speech and text, accurately acquire parameters in the multi-dimensional spatiotemporal data via a reasoning capacity of the vector spatiotemporal large model and a processing capacity of the agent, automatically update related multi-dimensional spatiotemporal data, and further achieve automatic generation and update of the multi-dimensional vector graphics or the thematic graphics-text documents. In the embodiments of the present disclosure, the multi-dimensional vector graphics refer to two-dimensional vector data, three-dimensional vector data, and temporal-dimensional vector data applied in the engineering field. The thematic graphics-text documents refer to graphics-text mixed document reports with specific meanings or applications of engineering.

Preferably, the step of achieving artificial intelligence understanding of the multi-dimensional vector graphics and various types of multi-dimensional spatiotemporal data, and interaction, analysis, and mutual generation of the multi-dimensional vector graphics and the thematic graphics-text documents by the intelligent information system application terminal includes: processing and understanding the multi-dimensional spatiotemporal data, generating a multi-dimensional spatiotemporal data processing agent, and mutually generating the multi-dimensional vector graphics and the thematic graphics-text documents, among them, the multi-dimensional spatiotemporal data processing agent refers to an agent that processes multi-dimensional spatiotemporal data, such as reading, editing, analyzing, etc., and specifically includes the following steps:
Step S1: inputting the multi-dimensional spatiotemporal data into the intelligent information system application terminal, converting the multi-dimensional spatiotemporal data into a natural language description processable for the vector spatiotemporal large model, and based on the reasoning and understanding capacities of the vector spatiotemporal large model, performing artificial intelligence analysis and understanding of multi-dimensional spatiotemporal information vector data and temporal data in the multi-dimensional spatiotemporal data.
Step S2: inputting user instructions in an interactive mode including speech input and text input, based on the understanding, analysis, and processing capacities of the vector spatiotemporal large model, and converting the user instruction input of the natural language description into formatted information system data edition, query, analysis, and output instructions to achieve generation of the multi-dimensional spatiotemporal data processing agent, wherein the speech input is converted into text via speech recognition.
Step S3: based on the multi-dimensional spatiotemporal information processing agent, performing fusion call and multi-round execution using the multi-dimensional spatiotemporal information processing agent to achieve automatic, intelligent automatic generation of the multi-dimensional vector graphics and the thematic graphics-text documents and bidirectional update of mutually generative artificial intelligence applications, and to achieve mutual generation of the multi-dimensional vector graphics and the thematic graphics-text documents.

In order to better express the structure of the mutually generative artificial intelligence system in FIG. 1, the intelligent information system application terminal achieves artificial intelligence understanding of the multi-dimensional vector graphics and various types of multi-dimensional spatiotemporal data, and elements of interaction, analysis, and mutual generation of the multi-dimensional vector graphics and the thematic graphics-text documents are illustratively shown, which does not mean that the intelligent information system application terminal only completes these technical contents. The elements include: processing and understanding of the multi-dimensional spatiotemporal data (i.e., artificial intelligence analysis and understanding of multi-dimensional spatiotemporal information vector data and temporal data in the multi-dimensional spatiotemporal data), generation of the multi-dimensional spatiotemporal information processing agent (i.e., generation of the multi-dimensional spatiotemporal data processing agent), and mutual generation of the multi-dimensional spatiotemporal information vector graphics and the thematic graphics-text documents (i.e., mutual generation of the multi-dimensional vector graphics and the thematic graphics-text documents).

Achieving the automatic generation of the multi-dimensional vector graphics or the thematic graphics-text documents specifically includes:
firstly, according to content requirements for the multi-dimensional vector graphics and the thematic graphics-text documents, artificially formulating a multi-dimensional vector graphics or thematic graphics-text document template, or automatically generating a thematic graphics-text document template by the vector spatiotemporal large model according to the content requirements, among them, graphics in the thematic graphics-text documents may be in a multi-dimensional vector graphics format or may be in a raster format converted from the multi-dimensional vector graphics; and then, through the query and analysis of an information system or the understanding and reasoning of the vector spatiotemporal large model, extracting and generating various types of parameters in the multi-dimensional vector graphics or thematic graphics-text document template, accurately acquiring parameters in the multi-dimensional vector spatiotemporal data, and finally, fusing the parameters with the template to generate the multi-dimensional vector graphics or the thematic graphics-text documents.

The multi-dimensional vector graphics and the thematic graphics-text documents are mutually generative based on the understanding and analysis capacities of the vector spatiotemporal large model, after related spatiotemporal information changes caused by entering the engineering field data or the thematic graphics-text documents, updated parameters, descriptions, or agents of the multi-dimensional vector graphics are generated by the vector spatiotemporal large model, and data of the multi-dimensional vector graphics is automatically updated.

After the multi-dimensional vector graphics change caused by drawing or modifying the multi-dimensional vector graphics, the changed multi-dimensional vector graphics are acquired by the vector spatiotemporal large model, corresponding engineering parameters or document descriptions are updated, and related contents of the thematic graphics-text documents are further updated to achieve the mutual generation of the multi-dimensional vector graphics and the thematic graphics-text documents.

FIG. 2 shows a flow chart of an application of an intelligent information system application terminal based on a vector spatiotemporal large model according to this embodiment. On the basis of the vector spatiotemporal large model, a natural language such as speech input and text input, multi-dimensional vector graphics, thematic graphics-text documents, and the like can be mutually expressed and generated. “Vector image and temporal understanding analysis”, “vector image and temporal application instruction”, and “information processing agent” in FIG. 2 may be understood in accordance with the foregoing steps S1 to S3, and will not be described in detail.

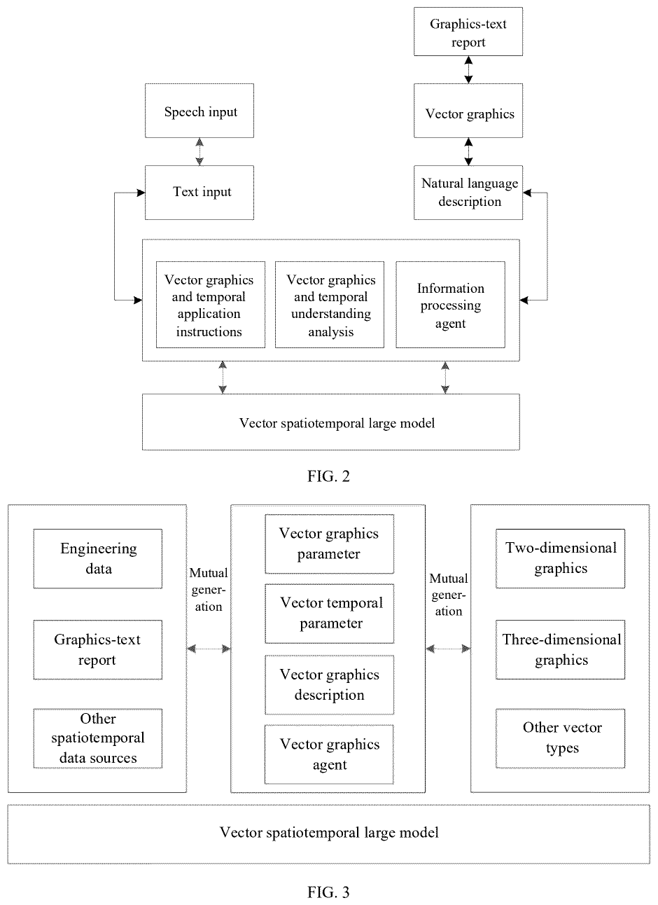

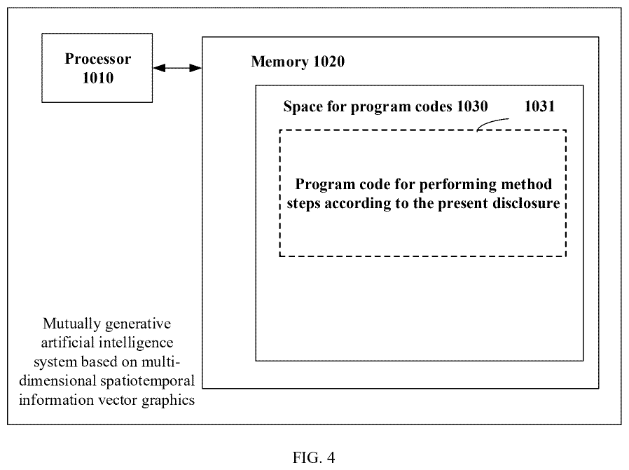

FIG. 3 shows a flow chart of achieving interaction, analysis, and mutual generation of multi-dimensional vector graphics and thematic graphics-text documents based on a vector spatiotemporal large model according to this embodiment. Based on the understanding and analysis capacities of the vector spatiotemporal large model, various types of multi-dimensional spatiotemporal data such as engineering field data, graphics-text documents, and other spatiotemporal data sources can be mutually generated and updated with various types of vector graphics (two-dimensional graphics, three-dimensional graphics, other vector types, and the like) and data (vector graphics parameters, vector temporal parameters, vector graphics descriptions, and vector graphics agents). Among them, the vector graphics agent refers to a small module that processes vector graphics (such as reading, editing, saving, etc.) tasks.

In summary, in the present disclosure, based on a GIS or a CAD platform and a data source, a multi-dimensional vector spatiotemporal large model terminal, a multi-dimensional spatiotemporal information processing agent terminal, and an intelligent information system application terminal are constructed. For multi-dimensional spatiotemporal data such as two-dimensional and three-dimensional vectors and temporal states, a large model having an understanding capacity for an engineering professional knowledge system, a data processing flow, multi-dimensional vector graphics, and thematic document structures is pre-trained to achieve the mutual expression and generation of multi-dimensional vector graphics, thematic spatiotemporal information, and professional document descriptions and to form an intelligent engineering field data processing system application. By establishing an artificial intelligence system in a human society engineering field, engineering technicians will be completely liberated, and an intelligent system support will be provided for automatic and rapid mutual processing of speech, text, multi-dimensional vector graphics, and thematic graphics-text documents in the related field. The present disclosure has higher practicability.

The embodiments of the mutually generative artificial intelligence system based on multi-dimensional spatiotemporal information vector graphics described above are merely schematic. The units described as separate components may or may not be physically separated, and the components displayed as units may or may not be physical units. In other words, the units or the components may be located in one place or may be distributed to a plurality of network units. Some or all of the modules may be selected according to actual requirements to achieve the object of the solution of this embodiment. It can be understood and implemented by a person of ordinary skill in the art without creative effort.

Various component embodiments of the present disclosure may be implemented in hardware, or in software modules running on one or more processors, or in combinations thereof. A person skilled in the art will appreciate that a microprocessor or a digital signal processor (DSP) may be used in practice to implement some or all of the functions of some or all of the components in an electronic device according to embodiments of the present disclosure. The present disclosure may also be implemented as device or apparatus programs (e.g., computer programs and computer program products) for performing some or all of the methods described herein. Such programs implementing the present disclosure may be stored on a computer-readable medium, or may have the form of one or more signals. Such signals may be downloaded from an Internet website, or provided on a carrier signal, or provided in any other form.

For example, FIG. 4 illustrates an implementable mutually generative artificial intelligence system based on multi-dimensional spatiotemporal information vector graphics according to the present disclosure. The mutually generative artificial intelligence system based on multi-dimensional spatiotemporal information vector graphics traditionally includes a processor 1010 and a computer program product or computer-readable medium in the form of a memory 1020. The memory 1020 may be an electronic memory such as a flash memory, an electrically erasable programmable read only memory (EEPROM), an EPROM, a hard disk, or a ROM. The memory 1020 has a storage space 1030 for program codes 1031 for performing any of the method steps in the aforementioned method. For example, the storage space 1030 for program codes may include various program codes 1031 for implementing various steps in the above method, respectively. These program codes may be read from or written into one or more computer program products. These computer program products include program code carriers such as hard disks, compact disks (CD), memory cards, or floppy disks. Such computer program products are generally portable or fixed storage units. The storage unit may have storage segments, storage spaces, and the like arranged similarly to the memory 1020 in the mutually generative artificial intelligence system based on the multi-dimensional spatiotemporal information vector graphics in FIG. 4. The program codes may, for example, be compressed in a suitable form. Generally, the storage unit includes computer-readable codes, i.e. codes that may be, for example, read by a processor such as the processor 1010. The codes, when executed by an electronic device, cause the electronic device to perform the various steps in the method described above.

It should be noted that the related contents of the mutually generative artificial intelligence system based on the multi-dimensional spatiotemporal information vector graphics in this embodiment may be referred to in the foregoing embodiments, and will not be described in detail herein.

Although preferred embodiments among the embodiments of the present disclosure have been described, additional changes and modifications may be made once a person skilled in the art is aware of basic inventive concepts. Accordingly, the appended claims are intended to be construed as including the preferred embodiments and all changes and modifications falling within the scope of the embodiments of the present disclosure.

Finally, it should also be noted that relational terms such as first and second are used only to distinguish one entity or operation from another entity or operation, and do not necessarily require or imply that any such actual relationship or sequence exists between the entities or operations herein. Moreover, the terms “include”, “comprise”, or any other variation thereof are intended to encompass a non-exclusive inclusion such that a process, method, article, or terminal device including a series of elements includes not only those elements but also other elements not explicitly listed, or elements inherent to such process, method, article, or terminal device. Without further limitation, an element defined by the statement “including a . . . ” does not preclude the presence of additional identical elements in a process, method, article, or terminal device including the element.

Although the embodiments of the present disclosure have been described above with reference to the accompanying drawings, the present disclosure is not limited to the aforementioned specific implementations, which are merely illustrative and not limiting. A person of ordinary skill in the art may make many forms under the inspiration of the present disclosure without departing from the spirit of the present disclosure and the scope of the claims, which are within the protection of the present disclosure.

1. A mutually generative artificial intelligence system based on multi-dimensional spatiotemporal information vector graphics, comprising a processor and a memory, wherein the memory has instructions stored therein, the instructions are executed by the processor correspondingly, and the processor is configured for:
uniformly expressing multiple types of spatiotemporal data, and constructing a multimodal vector spatiotemporal large model, wherein the vector spatiotemporal large model is used for understanding and analyzing a natural language description of multi-dimensional vector spatiotemporal data and strengthening a processing capacity for engineering field knowledge and a data processing flow, wherein the types of the spatiotemporal data comprise: text, speech, images, videos, and multi-dimensional vector graphics, and the natural language description of the multi-dimensional vector spatiotemporal data comprises the speech and the text;
based on learning and reasoning capacities of the vector spatiotemporal large model in combination with processing and analysis capacities of a geographic information system (GIS) or a computer-aided design (CAD) platform, learning and referring to a task execution process of a typical service flow, automatically analyzing a service flow task for processing interaction of the multiple types of spatiotemporal data, decomposing the service flow task into simple sub-tasks, and autonomously executing, transmitting, and solving the sub-tasks; and
based on reasoning and understanding capacities of the vector spatiotemporal large model, converting various types of multi-dimensional spatiotemporal data into corresponding natural language descriptions, completing agent-driven interaction, analysis, and mutual generation of the multi-dimensional vector graphics and thematic graphics-text documents in an engineering field via a simple input mode comprising the speech and the text, accurately acquiring parameters in the multi-dimensional spatiotemporal data based on a reasoning capacity of the vector spatiotemporal large model and a processing capacity of an agent, automatically updating related multi-dimensional spatiotemporal data, and further achieving automatic generation and updating of the multi-dimensional vector graphics or the thematic graphics-text documents;
wherein the process of constructing the vector spatiotemporal large model comprises: the natural language description of the multi-dimensional vector spatiotemporal data, pre-training and fine-tuning of the vector spatiotemporal large model, and understanding and analysis of the multi-dimensional vector spatiotemporal data;
a multi-dimensional vector spatiotemporal large model terminal fine-tunes a general large model using engineering field data as a pre-training data set, and uses the pre-training data set to pre-train the general large model by expanding an engineering field vocabulary to strengthen understanding and execution capacities of the general large model for the engineering field knowledge and the data processing flow;
the processor is further configured for: describing a processing flow of the engineering field data, defining a language of the processing flow of the engineering field data, training the general large model using the defined processing flow of the engineering field data as a fine-tuning data set, and strengthening understanding and execution capacities of the general large model for the processing flow of the engineering field data;
wherein the natural language description of the multi-dimensional vector spatiotemporal data comprises description conversion of various types of vector spatiotemporal data of points, lines, polygons, and solids having continuous spatial temporal (x, y, z, t) information and attribute information in various fields comprising the GIS and the CAD in a natural language mode according to requirements for training, understanding, and processing the vector spatiotemporal large model, and the converted natural language description has all information of original vector spatiotemporal data, comprising geometric types, geometric features, display styles, reference point coordinates, relative geometric data based on reference points, temporal information, and attribute information of vector objects;
the pre-training and fine-tuning of the vector spatiotemporal large model comprises: establishing a data set comprising the natural language description of the multi-dimensional vector spatiotemporal data and vector object features, and continuously pre-training and fine-tuning the general large model based on the pre-training data set and the fine-tuning data set to form the vector spatiotemporal large model having an understanding capacity for vector spatiotemporal data;
the understanding and analysis of the multi-dimensional vector spatiotemporal data comprises: inputting vector spatiotemporal data of the natural language description to the vector spatiotemporal large model, outputting understood vector object features by the vector spatiotemporal large model, inputting partial vector object features to the vector spatiotemporal large model, outputting understood or analyzed complete vector spatiotemporal data by the vector spatiotemporal large model, and based on output vector object spatiotemporal features or data, further completing understanding and processing of the geometric features, understanding and processing of attribute features, determination and processing of spatial relationships, and determination and processing of spatiotemporal relationships of the vector spatiotemporal data using an analysis capacity of the vector spatiotemporal large model;
wherein the understanding and processing of the geometric features of the vector spatiotemporal data comprises: processing geometric coordinates of the vector objects themselves;
the understanding and processing of the attribute features of the vector spatiotemporal data comprises: processing the attribute information of the vector objects themselves;
the determination and processing of the spatial relationships of the vector spatiotemporal data comprises: determining and processing a topological spatial relationship, a sequential spatial relationship, and a metric spatial relationship between the vector objects;
wherein establishing the data set comprising the natural language description of the multi-dimensional vector spatiotemporal data and the vector object features, and continuously pre-training and fine-tuning the general large model based on the pre-training data set and the fine-tuning data set comprises:
step T1: collecting massive vector spatiotemporal data, text natural language descriptions corresponding to the vector spatiotemporal data, and feature descriptions of the vector objects to form a vector spatiotemporal training data set, wherein the vector spatiotemporal data comprises predefined geometric structure information of points, lines, polygons, and solids, and attribute text information corresponding to geometry;
step T2: performing pre-training on the general large model as a base using the vector spatiotemporal training data set, performing vector text sampling by random walking, and inputting a sampled vector text as a training sample to the general large model for model fine-tuning; and
step T3: collecting a plurality of question answering pattern data comprising vector data-topological relationship, vector data-attribute information, and attribute description-vector data, forming a vector spatiotemporal model fine-tuning data set, and fine-tuning the general large model pre-trained in step T2;
the processor is further configured for: retrieving similar tasks in an engineering flow library according to a task description, wherein a task planning mode comprises no-feedback planning and feedback planning, and the processor is further configured for: feeding back an execution result from an environment, a user, or the vector spatiotemporal large model, and decomposing a service flow into a plurality of sub-tasks for execution;
the step of interacting, analyzing, and mutually generating the multi-dimensional vector graphics and the thematic graphics-text documents by the processor comprises: processing and understanding the multi-dimensional spatiotemporal data, generating a multi-dimensional spatiotemporal data processing agent, and mutually generating the multi-dimensional vector graphics and the thematic graphics-text documents, and further comprises:
step S1: inputting the multi-dimensional spatiotemporal data, converting the multi-dimensional spatiotemporal data into a natural language description processable for the vector spatiotemporal large model, and based on the reasoning and understanding capacities of the vector spatiotemporal large model, performing artificial intelligence analysis and understanding of multi-dimensional spatiotemporal information vector data and temporal data in the multi-dimensional spatiotemporal data;
step S2: inputting user instructions in an interactive mode comprising speech input and text input, based on the understanding, analysis, and processing capacities of the vector spatiotemporal large model, converting the user instruction input of the natural language description into formatted information system data edition, query, analysis, and output instructions, and generating the multi-dimensional spatiotemporal data processing agent; and
step S3: based on the multi-dimensional spatiotemporal information processing agent, performing fusion call and multi-round execution using the multi-dimensional spatiotemporal information processing agent to achieve automatic, intelligent automatic generation of the multi-dimensional vector graphics and the thematic graphics-text documents, and bidirectional update of mutually generative artificial intelligence applications, and to achieve mutual generation of the multi-dimensional vector graphics and various types of multi-dimensional spatiotemporal data; and
generating the multi-dimensional vector graphics or the thematic graphics-text documents comprises: accurately acquiring parameters in the multi-dimensional vector spatiotemporal data, and then fusing the parameters with a template to generate the multi-dimensional vector graphics or the thematic graphics-text documents.

2. The mutually generative artificial intelligence system according to claim 1, wherein the processing of the geometric coordinates of the vector objects comprises modification and editing of shape, size, and position; the processing of the attribute information of the vector objects comprises modification, query, analysis, and statistics; the topological spatial relationship refers to association, adjacency, inclusion, intersection, overlap, and separation relationships between spatial objects; the sequential spatial relationship refers to a spatial arrangement sequence of the spatial objects or events, comprising positional relationships such as front-back, left-right, up-down, and east-west-north-south; and the metric spatial relationship refers to a distance or proximity relationship between the spatial objects.

3. The mutually generative artificial intelligence system according to claim 1, wherein the processor is further configured for: decomposing and planning tasks of a vector graphics processing interactive service flow comprised in various types of multi-dimensional spatiotemporal data processing based on field knowledge, service flows, data understanding, and text generation capacities of the vector spatiotemporal large model, wherein sub-tasks are independently executed general logic processing or geographic information spatial analysis operation, have clear input and output, and are executed in conjunction to complete complex service flow processing;
when the tasks sense information from the environment or acquire information from storage, providing required data for the tasks, and storing process data in execution, wherein the multi-dimensional spatiotemporal information vector processing agent accumulates data and experience, and gradually completes self-evolution to provide an iterative capacity support for the vector spatiotemporal large model; and
executing the sub-tasks planned by the vector spatiotemporal large model as a specific result, wherein the task execution process depends on the reasoning capacity of the vector spatiotemporal large model, the spatial analysis and processing capacities of the geographic information system, and the processing capacity of the computer-aided design system, and interactive objects in the execution process comprise sensors, model libraries, controllers, and databases.

4. The mutually generative artificial intelligence system according to claim 1, wherein the plurality of sub-tasks are connected together in a cascade or tree-like mode, and after each sub-task is completed, a subsequent sub-task is determined according to a task execution result.

5. The mutually generative artificial intelligence system according to claim 3, wherein the processor is further configured for: storing information sensed from the environment, a task execution record, and a task execution result, and facilitating future actions using recorded memories, comprising memorized data and operations;
wherein the memorized data comprises a short-term memory of input information within a context window and a long-term memory of external vector storage retrieved by quick query.

6. The mutually generative artificial intelligence system according to claim 3, wherein the processor is further configured for: executing and completing various tasks using a tool, performing partial spatial analysis using a spatial database, complete specific tasks using models in a model library, and acquiring real-time or historical data using an application programming interface (API), wherein the tool comprises the vector spatiotemporal large model itself and external tools, comprising algorithm models, program compilation, databases, and APIs, and the specific tasks refer to tasks corresponding to the models in the model library.

7. The mutually generative artificial intelligence system according to claim 1, wherein achieving the automatic generation of the multi-dimensional vector graphics or the thematic graphics-text documents comprises:
according to content requirements for the multi-dimensional vector graphics and the thematic graphics-text documents, artificially formulating a multi-dimensional vector graphics or thematic graphics-text document template, or automatically generating a thematic graphics-text document template by the vector spatiotemporal large model according to the content requirements, wherein graphics in the thematic graphics-text documents are in a multi-dimensional vector graphics format or a raster format converted from the multi-dimensional vector graphics; and
through the query and analysis of an information system or the understanding and reasoning of the vector spatiotemporal large model, extracting and generating various types of parameters in the multi-dimensional vector graphics or thematic graphics-text document template, accurately acquiring parameters in the multi-dimensional vector spatiotemporal data, and fusing the parameters with the template to generate the multi-dimensional vector graphics or the thematic graphics-text documents.

8. The mutually generative artificial intelligence system according to claim 1, wherein the multi-dimensional vector graphics and the thematic graphics-text documents are mutually generative based on the understanding and analysis capacities of the vector spatiotemporal large model, after related spatiotemporal information changes caused by entering the engineering field data or the thematic graphics-text documents, updated parameters, descriptions, or agents of the multi-dimensional vector graphics are generated by the vector spatiotemporal large model, and data of the multi-dimensional vector graphics is automatically updated; and
after the multi-dimensional vector graphics change caused by drawing or modifying the multi-dimensional vector graphics, the changed multi-dimensional vector graphics are acquired by the vector spatiotemporal large model, corresponding engineering parameters or document descriptions are updated, and related contents of the thematic graphics-text documents are further updated.
